(19) United States
(12) Patent Application Publication
(10) Pub. No.: US 2026/0223611 A1
(43) Pub. Date: Jul. 30, 2026

(54) COMBINED SUBSTRATE, SUBSTRATE PROCESSING METHOD, AND SUBSTRATE PROCESSING SYSTEM

(71) Applicant: Tokyo Electron Limited, Tokyo (JP)

(72) Inventors: Yohei YAMASHITA, Kikuchi-gun, Kumamoto (JP); Yosuke NAKAMURA, Kikuchi-gun, Kumamoto (JP); Ryota ARAKAWA, Kikuchi-gun, Kumamoto (JP); Kazuhiro SHIBA, Kikuchi-gun, Kumamoto (JP)

(21) Appl. No.: 19/142,984

(22) PCT Filed: Dec. 13, 2023
(86) PCT No.: PCT/JP2023/044736

§ 371 Date: Jun. 25, 2025

(30) Foreign Application Priority Data
Dec. 26, 2022 (JP) 2022-208470

(51) Int. Cl. H10P 34/42; B23K 26/53; H10P 72/00

(52) U.S. Cl. CPC H10P 34/42; B23K 26/53; H10P 72/0428

(57) ABSTRACT

A combined substrate, in which a first substrate having at least a device layer and a first bonding film formed on a front surface thereof and a second substrate having at least a second bonding film formed on a front surface thereof are bonded to each other, is provided. An adhesion-reduced region formation film, whose adhesion to the first substrate is lower than adhesion to the first bonding film, is formed on the front surface of the first substrate to be located radially outward of a periphery removal starting point in the first substrate.

### TECHNICAL FIELD

The various aspects and embodiments described herein pertain generally to a combined substrate, a substrate processing method, and a substrate processing system.

### BACKGROUND

Patent document 1 discloses performing edge trimming, that is, removing a peripheral portion of a first wafer in a combined wafer in which the first wafer and a second wafer are bonded together. In the combined wafer, a laser absorption layer is formed at an interface between the first wafer and a device layer. By irradiating the laser absorption layer with laser light, a non-bonding region is formed, and the peripheral portion of the first wafer is removed.

### PRIOR ART DOCUMENT

Patent Document 1: International Publication No. 2021/199585

### DISCLOSURE OF THE INVENTION

### Problems to be Solved by the Invention

Exemplary embodiments provide a technique capable of appropriately removing a peripheral portion of a first substrate in a combined substrate in which the first substrate and a second substrate are bonded together.

### Means for Solving the Problems

In an exemplary embodiment, there Is provided a combined substrate in which a first substrate having at least a device layer and a first bonding film formed on a front surface thereof and a second substrate having at least a second bonding film formed on a front surface thereof are bonded to each other. An adhesion-reduced region formation film, whose adhesion to the first substrate is lower than adhesion to the first bonding film, is formed on the front surface of the first substrate to be located radially outward of a periphery removal starting point in the first substrate.

### Effect of the Invention

According to the exemplary embodiments, it is possible to appropriately remove the peripheral portion of the first substrate in the combined substrate in which the first substrate and the second substrate are bonded together.

### BRIEF DESCRIPTION OF THE DRAWINGS

FIG. 1 is a side view illustrating a schematic structure of a combined wafer.

FIG. 2 is a partially enlarged diagram illustrating the schematic structure of the combined wafer.

FIG. 3 is a plan view illustrating a schematic configuration of a wafer processing system.

FIG. 4 is an explanatory diagram showing a state in which an adhesion-reduced region at an interface between a first wafer and a film for forming the adhesion-reduced region.

FIG. 5 is an explanatory diagram illustrating a state in which a peripheral modification layer is formed inside the first wafer.

FIG. 6A and FIG. 6B are explanatory diagrams illustrating a state in which a peripheral portion of the first wafer is removed.

### DETAILED DESCRIPTION

In a manufacturing process for a semiconductor device, so-called edge trimming is performed, which involves removing a peripheral portion of a first wafer in a combined wafer in which the first wafer, which is a semiconductor substrate (hereinafter referred to as “wafer”) having a multiple number of devices such as electronic circuits formed on a surface thereof, is bonded to a second wafer.

When performing the edge trimming described in the aforementioned Patent Document 1, first, laser light is radiated to a laser absorption layer formed at an interface between the first wafer and a device layer to form a non-bonding region. Next, a modification layer serving as a starting point for removing the peripheral portion of the first wafer is formed inside the first wafer. Then, by inserting, for example, a blade into an interface between the first wafer and the second wafer, the peripheral portion of the first wafer is separated starting from the modification layer. Here, since the non-bonding region is formed at the interface between the first wafer and the device layer, the degree of bonding strength (adhesion) between the first wafer and the device layer is reduced, so that the peripheral portion is removed.

Here, in the combined wafer disclosed in the aforementioned Patent Document 1, although the laser absorption layer is formed at the interface between the first wafer and the device layer, a device layer including a laser absorption layer is not formed at a separation region where the peripheral portion is to be separated, and a bonding film for bonding to the second wafer may be formed on the surface of the first wafer. This bonding film is a film that is bonded to a bonding film of the second wafer, and is not a film provided for the purpose of separating the peripheral portion, so there may arise occasions where a separation surface may not be properly formed at an interface between the first wafer and the bonding film. That is, even if the laser light is radiated to separate the peripheral portion of the first wafer, there is a risk that the separation may occur at a location other than the interface between the first wafer and the bonding film. Therefore, there is still a room for improvement in the conventional method of removing the peripheral portion of the first wafer.

The present disclosure provides a technique capable of appropriately removing a peripheral portion of a first substrate in a combined substrate in which the first substrate and a second substrate are bonded together. Hereinafter, a wafer processing system as a substrate processing system and a wafer processing method as a substrate processing method according to an exemplary embodiment will be described with reference to the accompanying drawings. In the present specification and the drawings, parts having substantially the same functions and configurations will be assigned same reference numerals, and redundant descriptions thereof will be omitted.

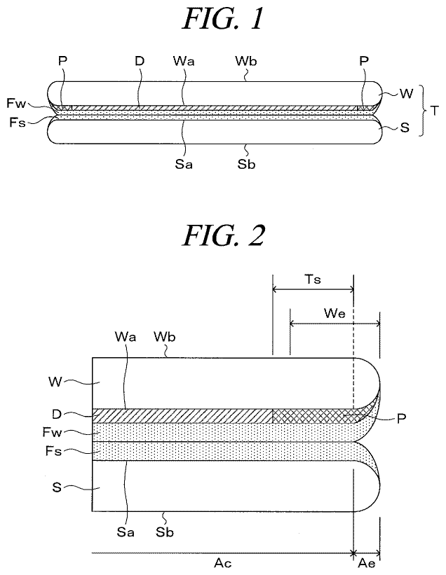

In a wafer processing system 1 according to the present exemplary embodiment, which will be described later, a processing is performed on a combined wafer T as a combined substrate in which a first wafer W as a first substrate and a second wafer S as a second substrate are bonded together, as shown in FIG. 1. Hereinafter, in the first wafer W, a surface that is bonded to the second wafer S is referred to as a front surface Wa, and a surface opposite the front surface Wa is referred to as a rear surface Wb. Likewise, in the second wafer S, a surface that is bonded to the first wafer W is referred to as a front surface Sa, and a surface opposite the front surface Sa is referred to as a rear surface Sb.

The first wafer W is a semiconductor wafer such as, but not limited to, a silicon substrate, and has a device layer D, a film P for forming an adhesion-reduced region (referred to as an adhesion-reduced region formation film P), and a first bonding film Fw formed on the front surface Wa side. The device layer D is formed on the front surface Wa, and has a substantially circular shape when viewed from the top. The adhesion-reduced region formation film P is formed on the front surface Wa to be located radially outward of the device layer D, and has a substantially annular shape when viewed from the top. The first bonding film Fw is stacked on the device layer D and the adhesion-reduced region formation film P. An interface between the device layer D and the first bonding film Fw and an interface between the adhesion-reduced region formation film P and the first bonding film Fw may be formed on a level with each other. Alternatively, the thickness of the adhesion-reduced region formation film P may be adjusted based on a relationship between a laser light absorptance of the adhesion-reduced region formation film P and separation of the first wafer W and the adhesion-reduced region formation film P. The thickness of the adhesion-reduced region formation film P may be, e.g., 100 nm to 500 nm, and the thickness of the first bonding film Fw may be, e.g., 200 nm to 1600 nm.

The device layer D includes multiple devices. The adhesion-reduced region formation film P absorbs laser light radiated by an adhesion-reduced region forming apparatus 50 to be described later. For the adhesion-reduced region formation film P, a film having a lower adhesion to the first wafer W than to the first bonding film Fw, such as an oxide film (SiO₂ film), is used. That is, an interface between the adhesion-reduced region formation film P and the first wafer W is easier to separate than the interface between the adhesion-reduced region formation film P and the first bonding film Fw. For the first bonding film Fw, an oxide film (a THOX film, a SiO₂ film, a TEOS film), a SIC film, a SiCN film, or an adhesive is used, for example. In addition, films of different materials are used for the adhesion-reduced region formation film P and the first bonding film Fw, and the compositions of the adhesion-reduced region formation film P and the first bonding film Fw are controlled so that their adhesions to the first wafer W meet the above-described relationship.

The second wafer S is also a semiconductor wafer such as, but not limited to, a silicon substrate, and a second bonding film Fs is formed on the front surface Sa. The second bonding film Fs is made of the same material as the first bonding film Fw. For example, an oxide film (THOX film, a SiO₂ film, a TEOS film), a SiC film, a SiCN film, or an adhesive may be used. In the present exemplary embodiment, the second wafer S is a support wafer that supports the first wafer W, but may be a device wafer. In this case, a device layer is formed on the front surface Sa of the second wafer S.

The combined wafer T is formed by bonding the first bonding film Fw of the first wafer W and the second bonding film Fs of the second wafer S.

As illustrated in FIG. 2, a peripheral portion of the first wafer W and a peripheral portion of the second wafer S are chamfered, and their thickness decreases toward edges thereof. At a peripheral portion of the combined wafer T, a non-bonding region Ae of the first bonding film Fw of the first wafer W and the second bonding film Fs of the second wafer S is formed, and a bonding region Ac is formed radially inward of the non-bonding region Ae.

A peripheral portion We of the first wafer W is a portion to be removed by edge trimming to be described later, and is in the range of, e.g., 0.5 mm to 3 mm from an outer edge of the first wafer W in a radial direction. An inner edge (starting point of the edge trimming) of the peripheral portion We is set in a trim starting point area Ts between a boundary between the device layer D and the adhesion-reduced region formation film P and at least a boundary between the non-bonding region Ae and the bonding region Ac.

In the present exemplary embodiment, the inner edge of the adhesion-reduced region formation film P is located radially inward of the peripheral portion We. Also, in the present exemplary embodiment, the outer edge of the adhesion-reduced region formation film P is located at the outer edge of the first wafer W. Here, however, it is sufficient that the outer edge of the adhesion-reduced region formation film P is located at the same position as or radially outward of the boundary between the non-bonding region Ae and the bonding region Ac (a boundary between a non-bonding position and a bonding position in the first bonding film Fw and the second bonding film Fs).

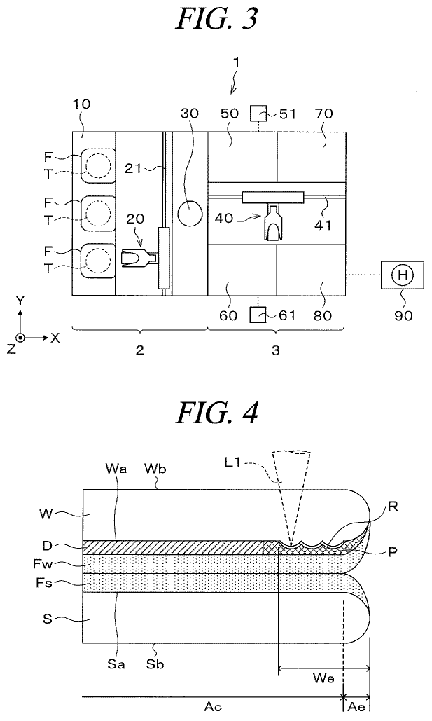

As shown in FIG. 3, the wafer processing system 1 has a configuration in which a carry-in/out station 2 and a processing station 3 are connected as a single structure. In the carry-in/out station 2, a FOUP F capable of accommodating a multiple number of combined wafers T is carried to/from, for example, the outside. The processing station 3 is equipped with various types of processing devices each configured to perform a required processing on the combined wafer T.

The carry-in/out station 2 is provided with a FOUP placement table 10 on which the FOUP F capable of accommodating the multiple number of combined wafers T is placed. A wafer transfer device 20 is disposed adjacent to the FOUP placement table 10 on the positive X-axis side of the FOUP placement table 10. The wafer transfer device 20 is configured to be movable on a transfer path 21 extending in the Y-axis direction to transfer the combined wafer T between the FOUP F of the FOUP placement table 10 and a transition device 30 to be described later.

In the carry-in/out station 2, the transition device 30 is disposed adjacent to the wafer transfer device 20 on the positive X-axis side of the wafer transfer device 20 to transfer the combined wafer T to/from the processing station 3.

The processing station 3 is equipped with a wafer transfer device 40, the adhesion-reduced region forming apparatus 50 as an adhesion-reduced region forming section, an internal modifying apparatus 60 as an internal modifying section, a periphery removing apparatus 70 as a periphery removing section, and a cleaning apparatus 80.

The wafer transfer device 40 is disposed on the positive X-axis side of the transition device 30. The wafer transfer device 40 is configured to be movable on a transfer path 41 extending in the X-axis direction, and is also configured to be able to transfer the combined wafer T to/from the transition device 30 of the carry-in/out station 2, the adhesion-reduced region forming apparatus 50, the internal modifying apparatus 60, the periphery removing apparatus 70, and the cleaning apparatus 80.

The adhesion-reduced region forming apparatus 50 radiates laser light (first laser light, e.g., CO₂ laser) to the adhesion-reduced region formation film P formed on the front surface Wa of the first wafer W, thereby forming an adhesion-reduced region R (see FIG. 4 below) in which the adhesion between the first wafer W and the adhesion-reduced region formation film P is reduced. The configuration of the adhesion-reduced region forming apparatus 50 is not particularly limited. Also, the adhesion-reduced region forming apparatus 50 has a control device 51 to be described later. In the present exemplary embodiment, “reduced adhesion” refers to a state in which the adhesion is reduced lower than that before the radiation of the first laser light, and includes separation of the first wafer W and the adhesion-reduced region formation film P.

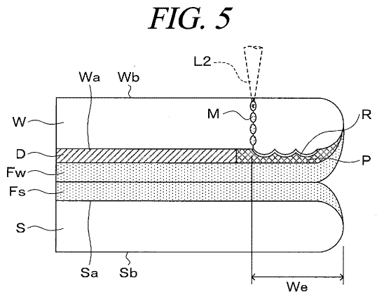

The internal modifying apparatus 60 radiates laser light (second laser light, e.g., YAG laser or fiber laser) to an inside of the first wafer W, thereby forming a peripheral modification layer M (see FIG. 5 below) which serves as a starting point for the separation of the peripheral portion We. The internal modifying apparatus 60 has a control device 61 to be described later.

The periphery removing apparatus 70 removes the peripheral portion We of the first wafer W, i.e., performs edge trimming, starting from the peripheral modification layer M formed in the internal modifying apparatus 60. The way to perform the edge trimming may be selected as required. As an example, in the periphery removing apparatus 70, a blade having a wedge shape may be inserted into an interface between the first wafer W and the second wafer S.

The cleaning apparatus 80 performs a cleaning processing on the first wafer W and the second wafer S after being subjected to the edge trimming in the periphery removing apparatus 70, and removes particles on these wafers. The way to perform the cleaning may be selected as required.

The above-described wafer processing system 1 is equipped with the control device 51, the control device 61, and a control device 90. The control device 51 controls the operation of the adhesion-reduced region forming apparatus 50 individually. The control device 61 controls the operation of the internal modifying apparatus 60 individually. The control device 90 performs an overall control of a series of processes of a wafer processing in the wafer processing system 1.

The control device 51, the control device 61, and the control device 90 process computer-executable instructions that cause the adhesion-reduced region forming apparatus 50, the internal modifying apparatus 60, and the wafer processing system 1, respectively, to perform various types of processes described in the present disclosure. The control device 51, the control device 61, and the control device 90 may be configured to control individual components of the adhesion-reduced region forming apparatus 50, the internal modifying apparatus 60, and the wafer processing system 1, respectively, to perform various processes described herein. In one embodiment, a part or the whole of the control device 51 may be included in the adhesion-reduced region forming apparatus 50, a part or the whole of the control device 61 may be included in the internal modifying apparatus 60, and a part or the whole of the control device 90 may be included in the wafer processing system 1.

Each of the control device 51, the control device 61, and the control device 90 may include a processor, a storage, and a communication interface. Each of the control device 51, the control device 61, and the control device 90 may be implemented by, for example, a computer. The processor may be configured to read out from the storage a program that provides a logic or routine that enables various control operations to be performed, and to perform the various control operations by executing the read program. This program may be stored in the storage in advance, or may be acquired via a medium when necessary. The acquired program is stored in the storage, and is read out from the storage and executed by the processor. The recording medium may be any of various types of computer-readable recording media, or may be a communication line connected to the communication interface. The recording medium may be transitory or non-transitory. The processor may be a central processing unit (CPU). The storage may include a random access memory (RAM), a read only memory (ROM), a hard disk drive (HDD), a solid state drive (SSD), or a combination thereof. The communication interface may communicate with the adhesion-reduced region forming apparatus 50, the internal modifying apparatus 60, and the wafer processing system 1 via a communication line such as a local area network (LAN).

In the present exemplary embodiment, the control device 51 and the control device 61 are installed separately for the adhesion-reduced region forming apparatus 50 and the internal modifying apparatus 60, respectively, but these control devices 51 and 61 may be integrated with the control device 90. In other words, the operations of the adhesion-reduced region forming apparatus 50 and the internal modifying apparatus 60 may be controlled by the control device 90.

Now, the wafer processing performed by using the wafer processing system 1 configured as described above will be explained. In the present exemplary embodiment, the first wafer W and the second wafer S are bonded together to form the combined wafer T in advance.

First, the FOUP F accommodating the multiple number of combined wafers T is placed on the FOUP placement table 10 of the carry-in/out station 2. Next, the combined wafer T is taken out from the FOUP F by the wafer transfer device 20 and transferred to the adhesion-reduced region forming apparatus 50 via the transition device 30 and the wafer transfer device 40.

In the adhesion-reduced region forming apparatus 50, first laser light L1 is radiated from the rear surface Wb of the first wafer W to the adhesion-reduced region formation film P formed on the front surface Wa of the first wafer W, as shown in FIG. 4. The first laser light L1 is radiated to a region between the inner edge (starting point of edge trimming) of the peripheral portion We and the boundary between the non-bonding region Ae and the bonding region Ac. The focal point of the first laser light L1 is adjusted to be positioned on the adhesion-reduced region forming film P. Once the first laser light L1 is radiated, the adhesion at the interface between the adhesion-reduced region formation film P and the first wafer W is reduced by a thermal stress generated by the radiation of the first laser light L1, so that an adhesion-reduced surface is formed. This adhesion-reduced surface becomes the adhesion-reduced region R.

The adhesion of the adhesion-reduced region formation film P to the first wafer W is lower than its adhesion to the first bonding film Fw. That is, the interface between the adhesion-reduced region formation film P and the first wafer W is easier to separate than the interface between the adhesion-reduced region formation film P and the first bonding film Fw. For this reason, the adhesion-reduced region R is formed at the interface between adhesion-reduced region formation film P and the first wafer W. In the edge trimming to be described later, when removing the peripheral portion We of the first wafer W, which is a target to be removed, the presence of this adhesion-reduced region R facilitates appropriate removal of the peripheral portion We.

The combined wafer T, in which the adhesion-reduced region R is formed at the interface between the adhesion-reduced region formation film P and the first wafer W, is then transferred by the wafer transfer device 40 to the internal modifying apparatus 60.

In the internal modifying apparatus 60, second laser light L2 is radiated to a preset radiation position inside the first wafer W to form the peripheral modification layer M, as illustrated in FIG. 5. This preset radiation position coincides with the inner edge of the peripheral portion We (starting point of edge trimming), and the peripheral modification layer M serves as a starting point when removing the peripheral portion We in the edge trimming to be described later. In the shown example, a crack develops vertically from the lowermost peripheral modification layer M, but the crack may also develop outwards in the radial direction. In such a case, a lower end of the crack from the lowermost peripheral modification layer M extends up to the inner edge of adhesion-reduced region formation film P. In other words, the inner edge of the adhesion-reduced region formation film P described above is formed at a position where it meets the lower end of the crack.

The combined wafer T with the peripheral modification layer M formed inside the first wafer W is then transferred to the periphery removing apparatus 70 by the wafer transfer device 40.

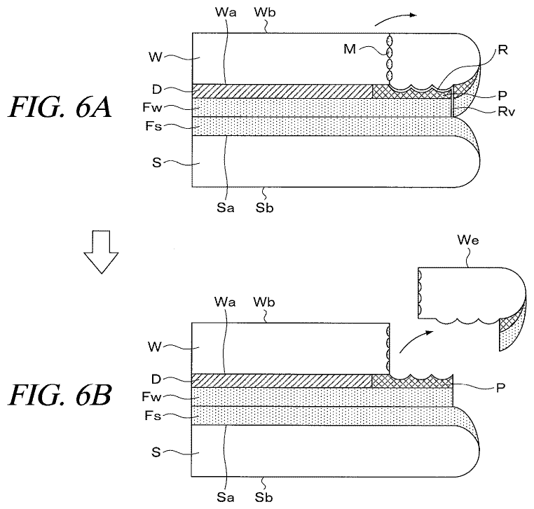

In the periphery removing apparatus 70, the removal of the peripheral portion We of the first wafer W, i.e., the edge trimming is performed, as shown in FIG. 6A and FIG. 6B. Here, as illustrated in FIG. 6A, since the bonding strength between the first bonding film Fw and the second bonding film Fs is low at an outer edge of the adhesion-reduced region R, i.e., at the boundary between the non-bonding region Ae and the bonding region Ac, an adhesion-reduced region Rv is formed, extending from the interface between the adhesion-reduced region forming film P and the first wafer W toward the interface between the first bonding film Fw and the second bonding film Fs. Then, as shown in FIG. 6B, the peripheral portion We is separated from a central portion (radially inward of the peripheral portion We) of the first wafer W, starting from the peripheral modification layer M, and is completely separated from the second wafer S, starting from the adhesion-reduced regions R and Rv.

The combined wafer T from which the peripheral portion We of the first wafer W has been removed is then transferred by the wafer transfer device 40 to the cleaning apparatus 80.

In the cleaning apparatus 80, either one or both of the first wafer W and the second wafer S after being subjected to the removal of the peripheral portion We are cleaned. For example, in the cleaning apparatus 80, by radiating cleaning laser light to the first wafer W and the second wafer S, the portions of the first and second wafers W and S irradiated with the cleaning laser light may be modified and removed, to thereby remove (clean) particles remaining on the first wafer W and the second wafer S.

Thereafter, the combined wafer T after being subjected to all the required processes is transferred to the transition device 30 by the wafer transfer device 40, and then transferred to the FOUP F of the FOUP placement table 10 by the wafer transfer device 20. In this way, the series of processes of the wafer processing in the wafer processing system 1 are completed.

According to the above-described exemplary embodiment, the adhesion-reduced region formation film P in the combined wafer T is formed radially outward of at least the inner edge (starting point of the edge trimming) of the peripheral portion We, and the adhesion of the adhesion-reduced region formation film P to the first wafer W is lower than the adhesion to the first bonding film Fw. Therefore, if the first laser light L1 is radiated to the adhesion-reduced region formation film P, the adhesion at the interface between adhesion-reduced region formation film P and the first wafer W is reduced, so the adhesion-reduced region R can be formed. That is, the adhesion-reduced region R can be appropriately formed at the required interface. Therefore, the peripheral portion We can be appropriately removed starting from this adhesion-reduced region R.

Further, the thickness of the adhesion-reduced region formation film P is set to be in the range of 100 nm to 500 nm, and the present inventors have confirmed that with this thickness, it is possible to form the adhesion-reduced region R at the interface between the adhesion-reduced region formation film P and the first wafer W and to remove the peripheral portion We. Moreover, the adhesion-reduced region formation film P having such a thickness may easily absorb the first laser light L1. Therefore, the adhesion-reduced region R can be formed by using the first laser light L1 with low energy.

Here, after performing the edge trimming of removing the peripheral portion We of the first wafer W, the first wafer W is thinned, and the device layer D is wet-etched. If the edge trimming is not performed appropriately, the second bonding film Fs of the second wafer S may be removed as well. In such a case, the second wafer S may be etched as well during the wet etching of the device layer D.

According to the present exemplary embodiment, however, since the peripheral portion We is removed starting from the adhesion-reduced region R formed at the interface between the adhesion-reduced region formation film P and the first wafer W, the second bonding film Fs of the second wafer S remains. Therefore, it is possible to suppress the second wafer S from being exposed and etched as in the conventional cases.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

1: Wafer processing system
50: Adhesion-reduced region forming apparatus
D: Device layer
Fw: First bonding film
P: Adhesion-reduced region formation film
Fs: Second bonding film
W: First wafer
S: Second wafer
T: Combined wafer

1. A combined substrate in which a first substrate having at least a device layer and a first bonding film formed on a front surface thereof and a second substrate having at least a second bonding film formed on a front surface thereof are bonded to each other,
wherein an adhesion-reduced region formation film, whose adhesion to the first substrate is lower than adhesion to the first bonding film, is formed on the front surface of the first substrate to be located radially outward of a periphery removal starting point in the first substrate.

2. The combined substrate of claim 1,
wherein the adhesion-reduced region formation film is formed to be located radially outward of the device layer.

3. The combined substrate of claim 2,
wherein the device layer is formed on the front surface of the first substrate,
the first bonding film is stacked on the device layer and the adhesion-reduced region formation film, and
a thickness of the adhesion-reduced region formation film is adjusted based on a relationship between a laser light absorptance of the adhesion-reduced region formation film and separation of the first substrate and the adhesion-reduced region formation film.

4. The combined substrate of claim 2,
wherein the adhesion-reduced region formation film is formed up to at least a boundary between a non-bonding position and a bonding position in the first bonding film and the second bonding film in a radial direction.

5. A substrate processing method, comprising:
preparing a combined substrate in which a first substrate having at least a device layer and a first bonding film formed on a front surface thereof and a second substrate having at least a second bonding film formed on a front surface thereof are bonded to each other, and in which an adhesion-reduced region formation film, whose adhesion to the first substrate is lower than adhesion to the first bonding film, is formed on the front surface of the first substrate to be located radially outward of a periphery removal starting point in the first substrate;
radiating first laser light to the adhesion-reduced region formation film from a rear surface of the first substrate to reduce adhesion between the adhesion-reduced region formation film and the front surface of the first substrate;
radiating second laser light to the periphery removal starting point in the first substrate to form a modification layer inside the first substrate; and
removing a peripheral portion of the first substrate, starting from the adhesion-reduced front surface of the first substrate and the modification layer.

6. The substrate processing method of claim 5,
wherein the first laser light is radiated up to a region between at least the periphery removal starting point in the first substrate and a boundary between a non-bonding position and a bonding position in the first bonding film and the second bonding film.

7. The substrate processing method of claim 5,
wherein the first laser light is radiated to the adhesion-reduced region formation film

8. A substrate processing system of processing a combined substrate in which a first substrate having at least a device layer and a first bonding film formed on a front surface thereof and a second substrate having at least a second bonding film formed on a front surface thereof are bonded to each other, the substrate processing system comprising:
an adhesion-reduced region forming apparatus,
wherein an adhesion-reduced region formation film, whose adhesion to the first substrate is lower than adhesion to the first bonding film, is formed on the front surface of the first substrate to be located radially outward of a periphery removal starting point in the first substrate, and
the adhesion-reduced region forming apparatus is configured to radiate first laser light to the adhesion-reduced region formation film from a rear surface of the first substrate to reduce adhesion between the adhesion-reduced region formation film and the front surface of the first substrate.

9. The substrate processing system of claim 8, further comprising:
an internal modifying section configured to radiate second laser light to the periphery removal starting point in the first substrate to form a modification layer inside the first substrate; and
a periphery removing section configured to remove a peripheral portion of the first substrate, starting from the adhesion-reduced front surface of the first substrate and the modification layer.
